(19) United States
(12) Patent Application Publication
(10) Pub. No.: US 2017/0338122 A1
(43) Pub. Date: Nov. 23, 2017

(54) Methods and Apparatus for Variable Selectivity Atomic Layer Etching

(71) Applicant: Jeffrey W. Daulton, Belmont, MA (US)

(72) Inventor: Jeffrey W. Daulton, Belmont, MA (US)

(21) Appl. No.: 15/665,036

(22) Filed: Jul. 31, 2017

Related U.S. Application Data
(63) Continuation of application No. PCT/US2016/017538, filed on Feb. 11, 2016.
(60) Provisional application No. 62/186,673, filed on Jun. 30, 2015.
(60) Provisional application No. 62/115,245, filed on Feb. 12, 2015.

(51) Int. Cl. H01L 21/306; H01J 37/32; H01L 21/02; H01L 29/778; H01L 29/205; H01L 29/66; H01L 29/20

(52) U.S. Cl. CPC H01L 21/30621; H01L 21/02241; H01J 37/3244; H01J 37/32357; H01L 29/2003; H01J 2237/1825; H01J 2237/334; H01J 2237/2001; H01L 29/205; H01L 29/66462; H01L 29/7787

(57) ABSTRACT

A method of fabricating a microelectronic device, such as a high electron mobility transistors (HEMT), is disclosed. In some examples, the method comprises placing a masked semiconductor sample into a treatment chamber. An oxidizing gas is introduced into the treatment chamber and ionized by an inductively-coupled plasma (ICP)-only plasma source to form a first plasma that oxidizes an exposed region of the sample surface. The oxidizing gas is then evacuated from the treatment chamber, and a reducing gas is introduced into the treatment chamber. The reducing gas in the treatment chamber is ionized via the ICP-only plasma source to form a second plasma that reduces the exposed region of the sample surface. The sample may be heated to a temperature of at least about 100° C. (e.g., 200° C.), resulting in the etching/removal of a portion of the exposed region of the sample via chemical conversion and thermal desorption.

### CROSS-REFERENCE TO RELATED PATENT APPLICATIONS

This application is a bypass continuation of International Application No. PCT/US2016/017538, filed Feb. 11, 2016, and titled “Methods and Apparatus for Variable Selectivity Atomic Layer Etching,” which claims priority, under 35 U.S.C. §119(e), from U.S. Application No. 62/115,245, filed Feb. 12, 2015, and titled “Variable Selectivity Atomic Layer Etching of AlGaN/GaN for Improved GaN HEMTs”; and U.S. Application No. 62/186,673, filed Jun. 30, 2015, and titled “Variable Selectivity Atomic Layer Etching of AlGaN/GaN for Improved GaN HEMTs.” Each of these applications is incorporated herein by reference in its entirety.

### GOVERNMENT SUPPORT

This invention was made with government support under Contract No. FA8721-05-C-0002 awarded by the U.S. Air Force. The government has certain rights in the invention.

### BACKGROUND

Microelectronic devices such as gallium nitride (GaN) heterogeneous field effect transistors (HFETs), also known as high electron mobility transistors (HEMTs), have properties that depend not only on their physical design, but also upon the microfabrication techniques used to produce them. Attempts have been made to convert depletion mode (“normally on”) HEMTs into enhancement mode (“normally off”) HEMTs, which are more easily used in circuit applications and can be paired with depletion-mode devices for more efficient circuits. These attempts have included modifying the aluminum gallium nitride (AlGaN) barrier layer in the transistor's gate region, for example, by growing a thinner layer of AlGaN across the HEMT, implanting fluorine in the gate region AlGaN, or dry etching the AlGaN in the region beneath the gate. However, each of these approaches suffers from drawbacks. Growing thinner AlGaN layers eliminates the low-resistance conductive path between the source and the drain of the HEMT. Fluorine implantation is a non-uniform process that imparts damage to the device and may lead to unpredictable stability of the HEMT's performance. Conventional dry etching of AlGaN relies on radio-frequency (RF) biasing that bombards the HEMT with ions, leading to device damage.

### SUMMARY

Embodiments of the present invention include a method of fabricating a microelectronic device, such as a HEMT. In some examples, the method comprises placing a semiconductor sample, with an etch mask defining an exposed region on at least one surface, into a treatment chamber. An oxidizing gas (e.g., oxygen (O₂), nitric oxide (NO), nitrous oxide (N₂O), and/or any other oxidant) is introduced into the treatment chamber and ionized by a remote plasma source to form a first plasma that oxidizes the exposed region of the sample surface. The oxidizing gas is then evacuated from the treatment chamber, and a reducing gas (e.g., boron trichloride (BCl₃), silicon tetrachloride (SiCl₄), carbon tetrachloride (CCl₄), other chlorocarbons (CₓCl_{y}), hydrochlorocarbons (CₓH_{y}Cl_{z}), and/or any other chloride-bearing reducing agent) is introduced into the treatment chamber. The reducing gas in the treatment chamber is ionized via the remote plasma source to form a second plasma that reduces the exposed region of the sample surface. The sample may be heated to a temperature of at least about 50° C.; when removal of Al-containing semiconductors is desired, the sample may be heated to at least about 100° C., 200° C., or higher temperatures while the method is performed. The method results in the etching/removal of a portion of the exposed region of the sample via chemical conversion and thermal desorption.

In some examples, the remote plasma source is an inductively-coupled plasma (ICP) source or a transformer coupled plasma (TCP) source. In some such cases, the method does not include, and specifically excludes, the application of an external electrical bias between the sample (or the substrate on which the sample is disposed) and the remote plasma source. (As appreciated by those of skill in the art, some self-bias may occur even if no external bias is applied.)

Prior to introducing the reducing gas into the treatment chamber, an inert purge gas may be introduced into the treatment chamber to displace the oxidizing gas and assist in its removal via a vacuum pump that is operably coupled to the treatment chamber. An inert gas, such as argon, helium, neon, or nitrogen, may also be introduced into the treatment chamber to aid ionization of the oxidizing gas and/or the reducing gas.

Another embodiment of the present invention includes an apparatus for remote plasma microfabrication of a sample. In some examples, the apparatus comprises a process chamber for processing a surface of the sample when it is received therein. The power supply is coupled to the process chamber, and is configured to power a remote plasma source (e.g., an ICP source and/or a TCP source) to deliver a remote plasma to the surface of the sample to alternately oxidize and reduce the surface of the sample. The apparatus also comprises a heater to heat the sample to a temperature sufficient to thermally desorb components of the surface of the sample. In some examples, a vacuum pump is coupled to the process chamber and configured to evacuate the process chamber between oxidizing and reducing the surface of the sample.

In still other embodiments, a method of patterning a III-N semiconductor substrate is described. In some such embodiments, a lithographic mask is formed on a III-N semiconductor substrate, and the III-N semiconductor substrate with the lithographic mask is placed into a vacuum chamber. The vacuum chamber is evacuated (e.g., via a vacuum pump), and the III-N semiconductor substrate is heated to a temperature of at least about 100° C. An oxidizing gas is introduced into the vacuum chamber, and ionized via an ICP source, so as to oxidize at least a portion of a surface of the III-N semiconductor substrate. The oxidizing gas is then evacuated from the vacuum chamber. A reducing gas is introduced into the vacuum chamber after the oxidizing gas has been evacuated from the vacuum chamber, and the reducing gas is ionized via the ICP source, so as to reduce the at least a portion of the surface of the III-N semiconductor substrate. The reducing gas is then evacuated from the vacuum chamber. The foregoing steps may be repeated in “cycles” until a desired etch depth is achieved. In some such embodiments, no bias is applied to the III-N semiconductor substrate while the patterning method is performed.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A is a block diagram of an atomic layer etching (ALE) apparatus for generating an ICP-only plasma.

FIG. 1B is a flow diagram of an ALE method compatible with the ICP-based apparatus of FIG. 1A.

FIG. 1C is a process flow diagram that illustrates sequential, or “digital” etching cycles.

FIG. 2A is a flow diagram of an ALE method compatible with the ICP-based apparatus of FIG. 1A.

FIG. 2B is a flow diagram of an ALE method compatible with the ICP-based apparatus of FIG. 1A.

FIG. 3A is a diagram showing an oxidation reaction between an oxygen (O₂) plasma and an aluminum gallium nitride (AlGaN) substrate, resulting in the formation of an aluminum gallium oxide (AlGaO) layer.

FIG. 3B is a diagram showing a reduction reaction between a boron trichloride (BCl₃) plasma and the AlGaO produced by the oxidation shown in FIG. 3A.

FIG. 4 shows a final step of the process flow of FIG. 1C, along with a micrograph and profilometry plot for the etched surface resulting from the process of FIGS. 3A-3B.

FIG. 5A is a plot of etch depth per cycle (in angstroms, Å) for AlGaN (with 27% Al) and GaN for varying BCl₃ cycle time.

FIG. 5B is a plot of etch depth per cycle, in Å, for AlGaN (with 27% Al) and GaN for varying O₂ cycle time.

FIG. 6A is a diagram of a cross-section of an HEMT stack.

FIG. 6B is a plot of etch depth (in nanometers, nm) for the HEMT of FIG. 6A and for GaN alone, for varying numbers of etch cycles at a temperature of 50° C.

FIG. 6C is a plot of etch depth, in nm, for the HEMT of FIG. 6A and for GaN alone, for varying numbers of etch cycles at a temperature of 220° C.

FIG. 7A is a plot of etch depth per cycle, in Å, for GaN, AlGaN with 17.6% Al, and AlGaN with 27.2% Al, for varying substrate temperature in ° C.

FIG. 7B is a plot of relative etch rate for AlGaN with 17.6% Al, and AlGaN with 27.2% Al, with respect to GaN, for varying substrate temperature in ° C.

FIG. 8A is an x-ray photoelectron spectroscopy (XPS) spectra plot (intensity vs. binding energy in electron volts, eV) for aluminum Al2p in AlGaN after exposure to O₂ and BCl₃ plasmas at 50° C. and at 220° C.

FIG. 8B is an XPS spectra plot for gallium Ga3d in AlGaN after exposure to O₂ and BCl₃ plasmas at 50° C. and at 220° C.

FIG. 9A is an XPS spectra plot for boron B1s in AlGaN after exposure to O₂ and BCl₃ plasmas at 50° C. and at 220° C.

FIG. 9B is an XPS spectra plot for boron B1s in GaN after exposure to O₂ and BCl₃ plasmas at 50° C. and at 220° C.

FIG. 10A is an XPS spectra plot for oxygen O1s in AlGaN after exposure to O₂ and BCl₃ plasmas at 50° C. and at 220° C.

FIG. 10B is an XPS spectra plot for oxygen O1s in GaN after exposure to O₂ and BCl₃ plasmas at 50° C. and at 220° C.

FIG. 11A is an XPS spectra plot for chlorine Cl2p_{3/2} in AlGaN after exposure to O₂ and BCl₃ plasmas at 50° C. and at 220° C.

FIG. 11B is an XPS spectra plot for chlorine Cl2p_{3/2} in GaN after exposure to O₂ and BCl₃ plasmas at 50° C. and at 220° C.

FIG. 12A shows AFM scans of GaN etched for 20 cycles.

FIG. 12B shows an AFM scan of as-grown GaN.

FIG. 12C shows an AFM scan of AlGaN etched for 20 cycles.

FIG. 12D shows an AFM scan of as-grown AlGaN.

FIG. 13A is a diagram of a cross-section of an as-grown AlGaN HEMT sample prior to ALE.

FIG. 13B shows the AlGaN HEMT of FIG. 14A after removal 10 nm of material via ALE.

FIG. 13C is an x-ray diffraction (XRD) omega scan/rocking curve showing intensities and full widths at half maximum (FWHM) for the as-grown AlGaN HEMT sample of FIG. 13A and the etched AlGaN HEMT sample of FIG. 13B.

FIG. 14 shows atomic force microscope (AFM) scans of a gallium nitride (GaN) film and a GaN HEMT epitaxial stack, each with an etched atomic step in the center.

FIG. 15A is a diagram of a cross-section of a depletion-mode GaN HEMT, showing a two-dimensional electron gas (“2DEG”) formed at the AlGaN-GaN interface.

FIG. 15B is an energy band diagram for the gate region of the HEMT of FIG. 15A.

FIG. 15C is a diagram of a cross-section of the GaN HEMT of FIG. 15A converted into an enhancement-mode GaN HEMT, showing a modified two-dimensional electron gas (“2DEG”) formed at the AlGaN-GaN interface.

### DETAILED DESCRIPTION

Group III-nitride (III-N) semiconductor materials have applications in optoelectronics (e.g., blue/green emitters, solid-state lighting, and UV detectors), power electronics (e.g., high-power high voltage power switches, power grids, power conditioners, solar inverters, electric cars) and RF electronics (e.g., RF transmitters with high power, voltage, and linearity; phased array radar). Gallium nitride (GaN) is of particular interest due to its unique properties, such as high bandgap and thermal conductivity, high-temperature operation, high breakdown field, and suitability for high voltage and high power applications. A comparison of electronic properties for GaN, silicon (Si), gallium arsenide (GaAs), 4H silicon carbide (4H-SiC) is shown in Table 1 below.

TABLE 1
Comparison of electronic properties for Si, GaAs, 4H-SiC and GaN

| | | Gallium | 4H Silicon | Gallium |
|---|---|---|---|---|
| | Silicon | Arsenide | Carbide (4H- | Nitride |
| | (Si) | (GaAs) | SiC) | (GaN) |
| Bandgap (eV) | 1.1 | 1.42 | 3.26 | 3.39 |
| Mobility, n (cm²/V * s) | 1350 | 8500 | 700 | 1200 |
| | | | | (bulk) |
| | | | | 2200 |
| | | | | (2DEG) |
| Saturation Velocity, n | 1.0 | 1.0 | 2.0 | 2.5 |
| (10⁷ cm/s) | | | | |
| Breakdown Field (MV/cm) | 0.3 | 0.4 | 3.0 | 3.3 |
| Thermal Conductivity | 1.5 | 0.43 | 3.3-4.5 | 2.0 |
| (W/cm * K) | | | | |
| Johnson's Figure of Merit | 1.0 | 2.7 | 20 | 27.5 |
| (FoM) (vₛₐₜ * E_{BD}) | | | | |
| Baliga FoM (εₛ * μ * E_{G}³) | 1.0 | 13.3 | 223 | 868 |

AlGaN/GaN HEMTs are high power, RF devices with a wide range of applications. The market for these devices is expected to exceed several billion dollars per year, with supporting tool markets into the hundreds of millions of dollars per year. Some approaches to the fabrication of advanced GaN HEMTs include the controlled recess etching of AlGaN and GaN layers. Specifically, recess etching may be applied to the source/drain regions of the HEMT, for example, to reduce on-resistance, and/or may be applied to the gate region of the HEMT, for example, to improve switching characteristics and shift the HEMT threshold voltage. Shifting the threshold voltage is useful, for example, in converting a depletion mode HEMT, which is normally on, into an enhancement mode HEMT, which is normally off and thus consumes less power. Because enhancement-mode devices are normally off, they tend to be safer for power switching applications. They also avoid the need for separate gate driver circuitry.

While transistor source-drain regions tolerate high levels of lattice damage induced by conventional plasma-based recess etching, this lattice damage is undesirable in the gate region, as it results in increases in both gate leakage and on-resistance, as well as unpredictable changes in threshold voltage, and cannot be removed through annealing. Uncontrolled variability in the threshold voltage shift may be due to (1) inherent nonuniformity of the etch rate across the chamber, (2) formation of trap states that change band offsets, (3) “smearing” of AlGaN/GaN interface from lattice damage. Formation of trap states can also inhibit switching speed of transistors.

“Digital etching” in conventional, parallel-plate reactive ion etching (RIE) systems (typically operating at 13.56 MHz) has been used to improve device performance in AlGaN/GaN HEMTs. In digital etching, two or more reactive gases are separated into two or more distinct reaction steps, such that not all reactive gases are being flowed into the chamber simultaneously. In other words, a digital etching processing may be characterized by (1) two or more reactive process gases, (2) introduction of the etch gases separated into distinct steps, and (3) steps separated in time to avoid mixing of reactive process gases.

During such methods, an RF bias is applied between two parallel-plate electrodes (one of which is electrically coupled to a platen on which the sample sits during processing) in the presence of boron trichloride (BCl₃) or oxygen (O₂), to alternately generate respective BCl₃ and O₂ plasma pulses. Such approaches rely on a self-limiting oxidation (via the O₂ plasma) of the semiconductor surface, followed by selective removal (via the BCl₃ plasma) of the oxidized material. RIE plasmas etch samples through a combination of chemical reactions and momentum transfer via physical bombardment of the sample surface. (Physical bombardment is often used for desorption of reaction products, e.g., in ion-assisted desorption.)

As such, these approaches do not allow for decoupling of chemical activation within the plasma from the physical component (i.e., the bombardment of positive ions which are accelerated towards the sample) induced by the applied RF bias and self-biasing of the sample, resulting in excess damage to the underlying material that can compromise ultimate device performance.

Systems and methods disclosed herein use inductively-coupled plasma reactive ion etching (ICP/RIE, e.g., using a 2.54 GHz power supply) techniques to reduce (minimize) ion bombardment and increase (maximize) the chemical component of BCl₃/O₂ digital etching, realizing true atomic layer etching (ALE) with less lattice damage than other techniques. More specifically, an electronic device made using ICP atomic layer etching may have (1) fewer defects (e.g., interstitials, vacancies, or substitutions), (2) less “smearing” of sharp interfaces, and/or (3) lower amorphization (generally accumulated defect generation). An ICP-only plasma without an applied RF bias achieves etch rate selectivity between GaN and AlGaN, as well as the ability to control or vary this selectivity by varying substrate temperature. Variable selectivity allows for a wide range of device opportunities, particularly at the shallow etch depths used to make millimeter-wave devices.

Etch processes described herein use an alternating series of O₂ and BCl₃ plasma pulses in a manner such that the two gases are not introduced into the treatment chamber (also referred to herein as a “process chamber” or “vacuum chamber”) at the same time. (There may be some residual gas adsorbed onto the chamber walls.) This is accomplished by pumping the treatment chamber to a predetermined vacuum level using a vacuum pump (e.g., a turbopump, physical displacement pump, cryopump, and/or the like) that is plumbed to the treatment chamber. Systems described are optionally further equipped with a gas inlet to purge the treatment chamber with an inert gas (such as argon or nitrogen) to assist in removing trace amounts of the O₂ and/or BCl₃ that may remain in the treatment chamber after vacuum pumping, for example, to avoid undesirable reactions between the two etch gases that can result in deposition in the chamber.

According to some embodiments, an ICP-only plasma (where little to no external RF or DC bias is applied, or where the RF bias power is kept at 0 watts) is used to chemically activate the surface of a semiconductor sample (e.g., a III-Nitride (III-N) material or a III-Arsenide (III-As) material, for example, aluminum gallium nitride (AlGaN) and/or aluminum nitride (AlN)) without introducing significant substrate bias at the sample surface, thereby reducing or minimizing damage to the underlying crystal lattice. (There may be some self-bias from the ICP plasma, e.g., with a magnitude less than about 10 V.) An oxygen plasma oxidizes the sample surface, and the subsequent BCl₃ plasma selectively removes the oxidized material, allowing for etch rates of about 1 Å per second, or about 2.5 Å to about 5 Å per cycle, or about 10 Å per cycle, etc., depending on etch temperature. ICP-only plasma operation, without RF bias power, allows for controlled selective etching of GaN over AlGaN by varying the substrate temperature without the need for fluorine-containing gases, which can react with Al to form non-volatile (and non-reactive) AlFₓ products, which inhibit further etching. For example, operation at a substrate temperature of 50° C. results in a AlGaN etch rate that is more than 16 times slower than a GaN etch rate, while a substrate temperature of 220° C. results in nearly identical GaN and AlGaN etch rates.

Without wishing to be bound by any particular theory, the inventor believes that etching samples using an ICP-only plasma takes place through primarily chemical mechanisms, and the ion bombardment of the semiconductor surface of traditional parallel-plate RIE methods is reduced or eliminated, thereby minimizing the plasma damage imparted to the sample being processed.

Applications of embodiments described herein include high-power GaN HEMTs for power switching applications. They can also be used to fabricate enhancement-mode and depletion-mode devices on the same wafer with the same epitaxy, e.g., for logic or RF circuits, The controlled recess etching facilitated by the systems and methods described herein allows for improved source/drain contacts with a high degree of cross-wafer physical uniformity, which provides more consistent contact resistance across the wafer. Additionally, controlled recess etching allows for increased threshold voltages (e.g., for the fabrication of enhancement mode devices) and improved switching characteristics, such as higher transconductance, faster switching, and reduced short channel effects, when applied to a gate recess.

Methods described herein achieve controlled, low-damage recess etching for AlGaN/GaN HEMT gates and/or source/drain regions, allowing for better switching characteristics and improved on-resistance for the devices. These methods may also be applied to other device topologies in the AlGaN/GaN material system or to other devices for which sidewall smoothing or other types of micro-damage removal is useful (e.g., to remove damage imparted to a sample via a Bosch process or deep reactive ion etch (DRIE)). They can also be used to clean up damage imparted to a GaN surface of a sample by a Bosch process. These processes also allow controlled recess for electrical access to thin buried layers that may or may not have a compositional etch stop.

ICP-Only ALE Plasma System

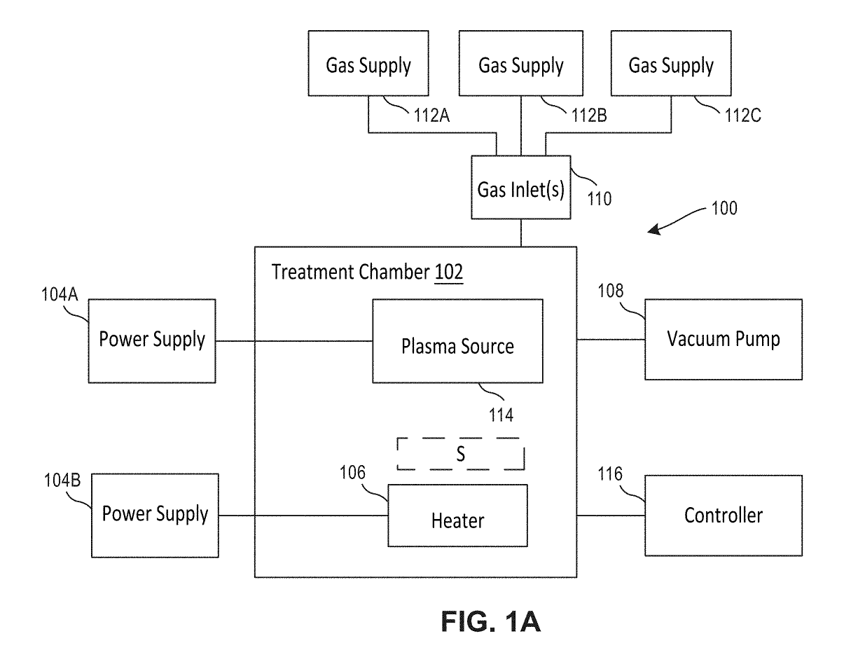

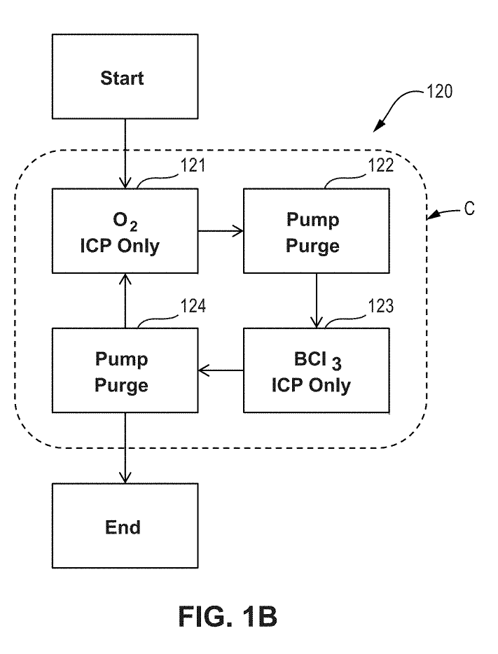

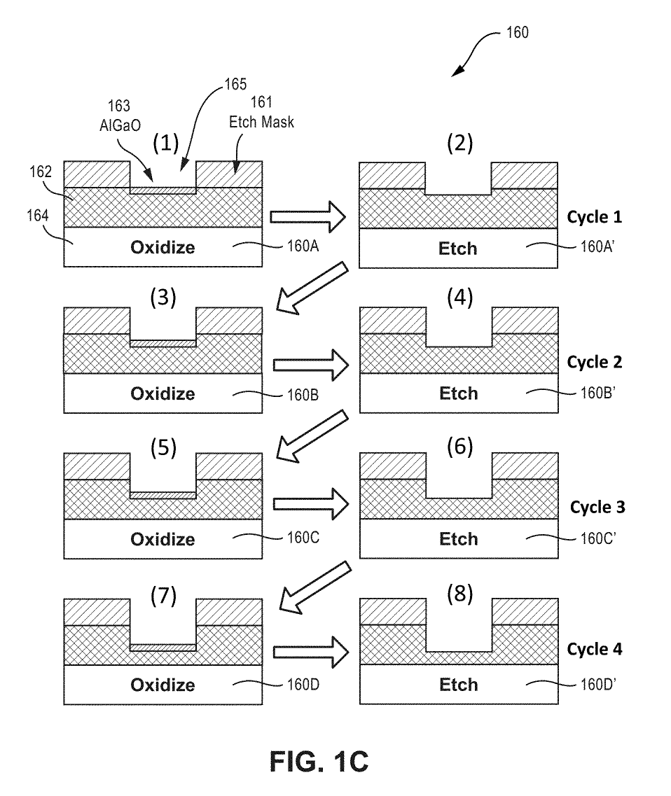

Turning now to the drawings, FIG. 1A is a block diagram of an ALE apparatus. The apparatus 100 includes a treatment chamber 102, with a plasma source 114, a heater 106, and a sample S disposed in thermal communication with the heater 106 within the treatment chamber 102. The treatment chamber can be a vacuum chamber with one or more vacuum seal interfaces, electrical feedthroughs, gas inlets 110, cooling water plumbing, loadlock mechanisms, pressure sensors, sample platens, rotational or translation motors, and/or the like. The power supply 104A is any remote plasma source, such as an inductively-coupled plasma (ICP) source (e.g., a Samco RIE-200iP) or a transformer coupled plasma (TCP) source. The power supply 104A is electrically coupled to the plasma source 114 and configured to supply power to the plasma source 114 so as to generate a plasma in the presence of a suitable gas. The heater 106 is also electrically coupled to a power supply 104B, which supplies power to heater to heat the sample S during the etching process. A vacuum pump 108 (e.g., a turbopump, roughing/physical displacement pump, cryopump, etc.) is coupled to the treatment chamber 102 and configured to evacuate the treatment chamber 102 to a suitable vacuum level (e.g., to a pressure of 1×10⁻⁴, 1×10⁻⁵, 1×10⁻⁶ Torr or below; higher pressures may be possible if a purge gas is utilized).

One or more gas inlets 110 are coupled to the treatment chamber 102 and configured to transmit one or more associated gases from a gas supply (of gas supplies 112A, 112B, 112C). Although shown in FIG. 1A to include three gas supplies, the apparatus 100 may include only two gas supplies, or as many as four or more gas supplies. A single gas inlet may correspond to a single gas supply or to multiple gas supplies. A mass flow controller can be included in any of the gas plumbing circuits defined by the gas supplies (e.g., gas supply 112A, 112B, 112C) and the gas inlet(s) 110, to monitor the flow rate of the corresponding gas. In some configurations, gas supply 112A is an oxidizing gas such as oxygen O₂, gas supply 112B is a reducing agent such as boron trichloride (BCl₃) or silicon tetrachloride (SiCl₄), and gas supply 112C is an inert gas, such as argon (Ar) or nitrogen (N₂), for purging the treatment chamber 102.

In some cases, a controller 116 (e.g., a computer) is operably coupled to various components of the apparatus 100 such that an operator can program/control parameters such as the power levels of each of the power supplies 104A, 104B, gas supply selection, gas flow rates, vacuum pumping level, number of cycles, etch duration, etc.

ICP-Only ALE Methods

FIG. 1B is a block diagram of an ALE method 120 that can be carried out with the ICP-based apparatus 100 of FIG. 1A. As shown in FIG. 1B, the method 120 begins with oxidizing a sample in a treatment chamber using an ICP-only (i.e., with little to no external bias applied between the sample platen and an electrode of the plasma source, e.g., about 0-10 V bias) O₂ plasma, possibly with an inert carrier gas, such as Ar, He, Ne, or N₂. The ICP O₂ plasma is generated by applying power (e.g., about 40 W or about 50 W) to the ICP plasma source in the presence of O₂ at a predetermined pressure in the treatment chamber (e.g., about 37.5 mTorr). Reactive species may be allowed to diffuse to the wafer surface, as opposed to being accelerated into the surface as is the case for conventional RIE or ICP-RIE.

After the plasma oxidation, a pump purge 122 is performed, in which the treatment chamber is evacuated using the vacuum pump, and with an inert purge gas (e.g., Ar, He, Ne, N₂) flowing at least part of the time, to remove substantially all oxygen and plasma processing byproducts from the treatment chamber (e.g., until a predetermined vacuum level is achieved). The purge could take the form of (1) pump, (2) pump-purge-pump, (3) pump-purge, etc. Flowing of purge gas is generally done with vacuum valve partially open to maintain a set pressure for the fixed flow rate.

Next, the sample (which has been oxidized as part of step 121) is exposed to a reducing environment via an ICP-only BCl₃ plasma 123 (possibly with an inert carrier gas), such that the oxidized sample surface is reduced. The ICP BCl₃ plasma is generated by applying power (e.g., about 40 W or about 50 W) to the ICP plasma source, in the presence of BCl₃ at a predetermined pressure in the treatment chamber (e.g., about 37.5 mTorr).

After the plasma reduction 123, a further pump purge 124 is performed, so as to remove substantially all BCl₃ and plasma processing byproducts from the treatment chamber (i.e., until a predetermined vacuum level is achieved).

The sequence of steps 121, 122, 123 and 124 may be referred to collectively as a processing “cycle” (see “C” in FIG. 1B). One or more cycles can be performed to fully process a sample, depending upon the desired etch depth.

As discussed above, the sample may be heated by a heater during processing. Because physical bombardment of the sample surface is minimized or eliminated due to the ICP-only nature of the plasma generation, etching of the sample takes place as a result of the chemical reduction of the oxidized sample surface and thermal desorption, which may be assisted using the sample heater. Also, there may be little to no sputtering of the sample surface from ion bombardment, thus resulting in a low-damage etched surface. The oxidation and reduction/etch steps are separated by pump/purge steps.

When designing an etch process (i.e., selecting plasma power applied, oxidation and etch duration(s), vacuum level, gas flow rate, and/or the like), certain tradeoffs exist. For example, higher plasma power levels can be used, so as to achieve decreased etch time, but at the risk of increased damage to the sample. Similarly, the pressure can be increased, leading to a reduced mean free path for ions, reduced interaction with walls, lower average ion energy, and the potential for active species generated by the plasma to become less active by the time they arrive at the surface. Also, it can become difficult to sustain the plasma if the pressure is too high or too low.

Digital Etching

FIG. 1C is a process flow diagram that illustrates digital etching cycles, similar to the cycles described above with reference to FIGS. 1B (above) and 2A-2B (below), according to methods described herein. Digital etching processes may be entirely dry and may utilize only low-energy ions. As shown in FIG. 1C, a process flow 160 includes four cycles (Cycles 1-4), each including an oxidize step (160A-160D′) and an etch (or reduction) step (160A′-160D′).

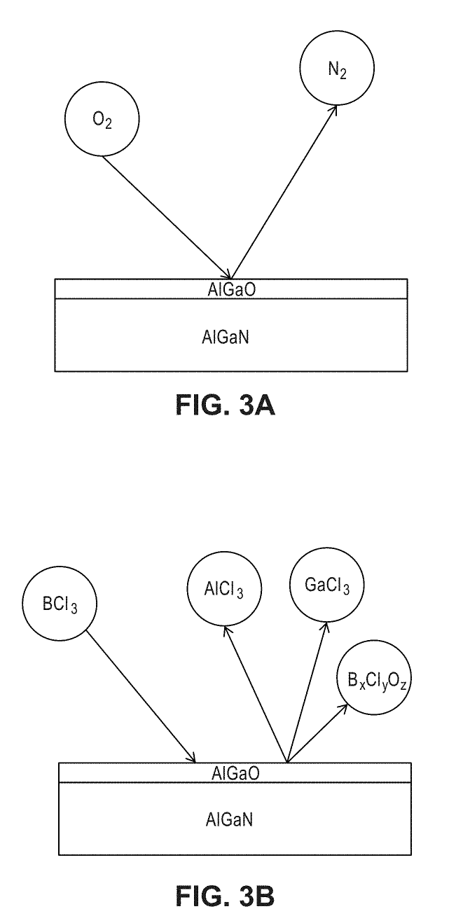

A sample being processed according to the process 160 includes a GaN layer 164, an AlGaN layer 162, and a lithographically defined etch mask 161 that includes openings 165 that expose portions of the surface of the AlGaN layer 162. During oxidation (i.e., in the presence of an O₂ plasma), at step (1) (160A), the AlGaN layer 162 exposed via the opening(s) in the etch mask 161 becomes oxidized (as shown and discussed below with reference to FIG. 3A) and an AlGaO layer 163 forms in the opening(s) 165 in the etch mask 161. During etching (e.g., in the presence of a BCl₃ plasma and/or heat applied to the sample), at step (2) (160A′), the AlGaO layer 163 is etched, and a recess or trench is defined within the AlGaN layer 162.

Moving on to step (3) (160B), the exposed surface of the AlGaN layer 162, which now has a larger surface area by virtue of the recess sidewalls, is again oxidized, and then etched again at step (4) (160B′), completing Cycle 2. Steps (5)-(8) (160C-160D′) proceed in a similar fashion until a total of four etch cycles have been completed, resulting in a substantially thinned central region of the AlGaN layer 162. Once all desired oxidize/etch cycles are completed, and a desired AlGaN layer 162 thickness is achieved, the etch mask 161 may be removed for further processing of the sample into a completed device or product.

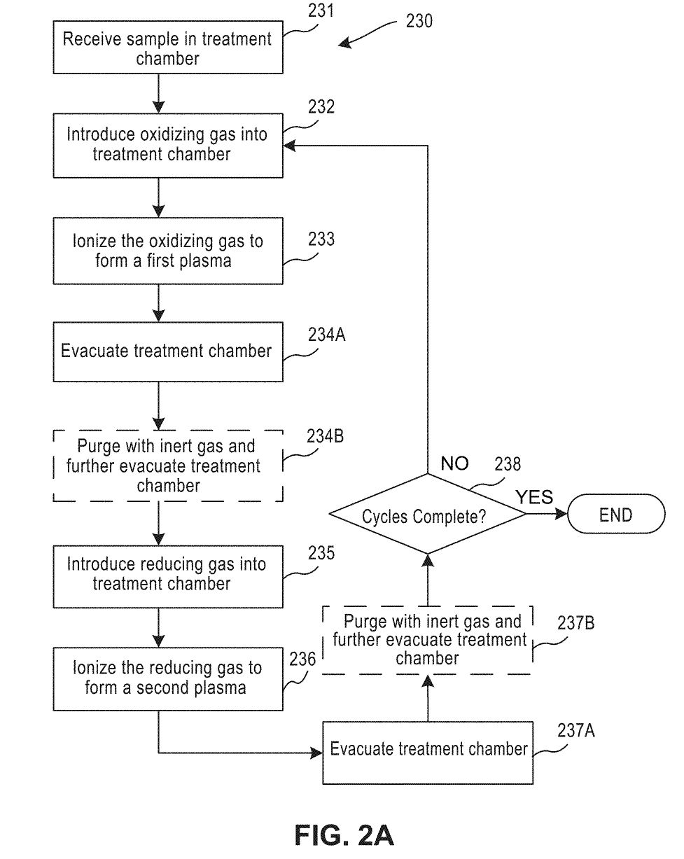

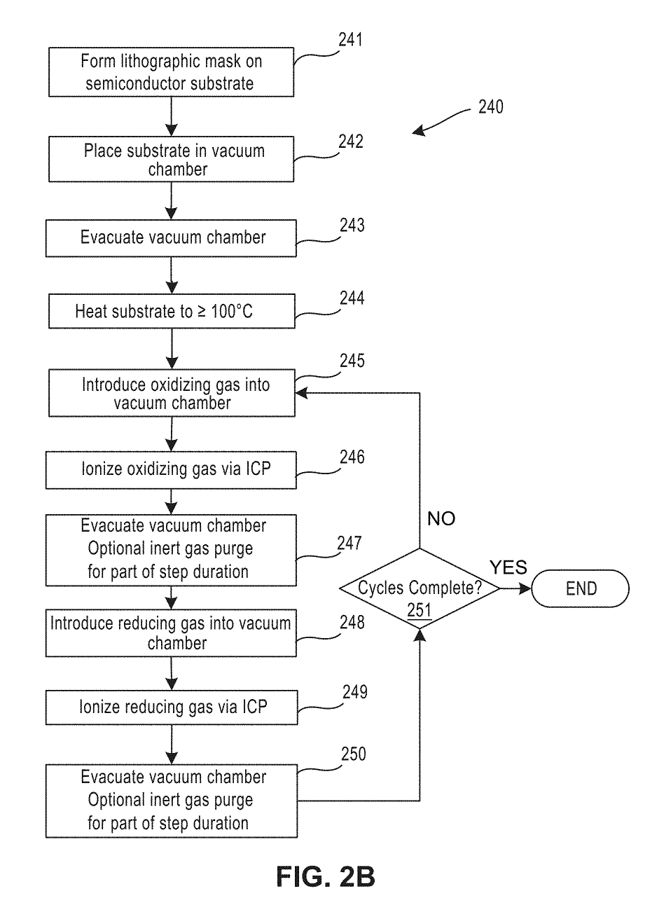

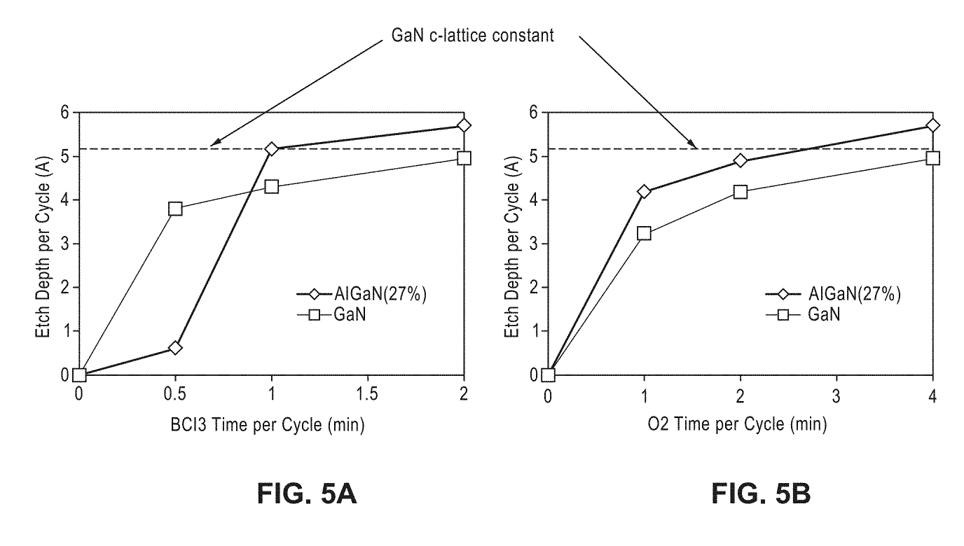

FIG. 2A is a flow diagram of an ALE method 230 compatible with the ICP-based apparatus of FIG. 1A. As shown in FIG. 2A, the method 230 begins with a sample being received in a treatment chamber 231. Once the sample is loaded, the treatment chamber may be closed, sealed, and pumped down to a desirable base pressure using a vacuum pump. Once the desired vacuum level is reached, an oxidizing gas is introduced into the treatment chamber 232, and the oxidizing gas is ionized 233, using an ICP-only remote plasma source, to ignite and form a stabilized first plasma. After a predetermined duration (e.g., 45 seconds, 90 seconds, etc.), during which time the first plasma is maintained within the treatment chamber and works to oxidize any exposed regions of the sample surface, the oxidizing gas supply is shut off (for example, by shutting an associated valve, e.g., via a controller), and the treatment chamber is evacuated 234A using the vacuum pump. The duration can be adjusted as desired, e.g., using the results shown in FIGS. 5A and 5B. For instance, the duration may be selected to avoid reaching full saturation of the surface in order to save processing time.

In some cases, as discussed above, the treatment chamber is also purged with an inert gas 234B concurrently with the vacuum pumping for a predetermined duration and/or at a predetermined gas flow. The purge may be done by a residual gas analyzer (RGA), typically on the order of 1 minute depending on the purge flow, chamber wall temperature, chamber volume, etc. In such embodiments, at some point, the inert purge gas is shut off and the vacuum pump continues to pump on the treatment chamber until a desired base vacuum (e.g., 10⁻⁴ Torr) is achieved in the treatment chamber. The base vacuum may be higher and may depend on chamber volume, chamber surface area, and wall temperature.

Once the desired base vacuum is achieved, a reducing gas is introduced into the treatment chamber 235, and the reducing gas is ionized, using an ICP-only remote plasma source, to ignite and form a stabilized second plasma. After a predetermined duration, during which time the first plasma is maintained within the treatment chamber and works to reduce the oxidized exposed regions of the sample surface, the reducing gas supply is shut off (for example, by shutting an associated valve, e.g., via a controller), and the treatment chamber is again evacuated 237A using the vacuum pump (and, optionally, purged 237B as described above with reference to 234B).

At this point, after steps 232 through 237A/B have been finished, a single process cycle has been completed. If the number of process cycles is completed at 238 (as determined, for example, via a controller by comparison of a cycle count with a predetermined/pre-programmed number of cycles), the process ends. If additional cycles are to be performed, the method 230 loops back to step 232 and repeats until all cycles have been performed. For any of the steps of FIG. 2A, the sample may be heated by a sample heater, such as a recirculating heater or a resistive heater, within the treatment chamber.

FIG. 2B is a flow diagram of an ALE method 240 compatible with the ICP-based apparatus of FIG. 1A. As shown in FIG. 2B, the method 240 begins with forming a lithographic mask 241 (e.g., via photolithography), comprising a mask material such as nickel, silicon dioxide, photoresist, etc., on a semiconductor substrate such that patterned openings are defined therein exposing regions of the sample surface. The patterned substrate is placed into a vacuum chamber 242, and the treatment chamber is evacuated 243 using a vacuum pump.

The substrate is heated 244 with a heater to a predetermined temperature, for example about 50° C., about 100° C., about 200° C., about 220° C., etc. For GaN/AlGaN systems, 100° C. is the crossover point for selectivity to AlGaN. Below this temperature, the etch will only etch GaN, but above it, both etch at roughly the same rate (within about 10-20° C. above and below). 100° C. or so is the minimum temperature to remove AlGaN; GaN is removed at much lower temperatures Other parameters that may affect the crossover point include pressure and stoichiometry, e.g., to the point of full AlCl₃ surface coverage (full depletion of surface Ga). Higher Al fractions may achieve saturation after a smaller number of cycles.

An oxidizing gas is introduced into the vacuum chamber 245 via one or more gas inlets (e.g., at a predetermined flow rate). The oxidizing gas within the treatment chamber is ionized 246 using an ICP-only plasma source (e.g., at a power of about 40 W or about 50 W) to form an oxidizing plasma to oxidize the regions of the substrate exposed via the lithographic mask. After a predetermined duration, the plasma power is shut off and the vacuum chamber is evacuated 247 using a vacuum pump. Optionally, for at least a portion of the pumping time, a purge gas may be flowed to assist in the removal of gases in the vacuum chamber during evacuation 247.

Once a desired vacuum level is reached, a reducing gas is introduced into the vacuum chamber 248 via one or more gas inlets (e.g., at a predetermined flow rate), and the reducing gas within the treatment chamber is ionized 249 using an ICP-only plasma source (e.g., at a power of about 40 W or about 50 W) to form a reducing plasma to reduce/etch the oxidized regions of the substrate exposed via the lithographic mask. After a predetermined duration, the plasma power is shut off and the vacuum chamber is again evacuated 250 using a vacuum pump. Again, optionally, for at least a portion of the pumping time, a purge gas may be flowed to assist in the removal of gases in the vacuum chamber during evacuation 250.

At this point, after steps 245 through 250 have been finished, a single process cycle has been completed. If the number of cycles is completed at 251 (as determined, for example, via a controller by comparison of a cycle count with a predetermined/pre-programmed number of cycles), the process ends. If additional cycles are to be performed, the method 240 loops back to step 245 and repeats until all cycles have been performed.

Reaction Chemistry

FIG. 3A is a diagram showing an oxidation reaction between an oxygen (O₂) plasma and an aluminum gallium nitride (AlGaN) substrate, resulting in the formation of an aluminum gallium oxide (AlGaO) layer. As shown in FIG. 3A, O₂ plasma reacts with the AlGaN surface to form a surface oxide (aluminum gallium oxide, AlGaO), and also liberates nitrogen gas.

FIG. 3B is a diagram showing a reduction reaction between a boron trichloride (BCl₃) plasma and the AlGaO produced by the oxidation shown in FIG. 3A. The BCl₃ plasma strongly reduces III-oxides such as AlGaO, and generates reaction byproducts that primarily include aluminum chloride (AlCl₃), gallium trichloride (GaCl₃), and byproducts having the form BₓCl_{y}O_{z}.

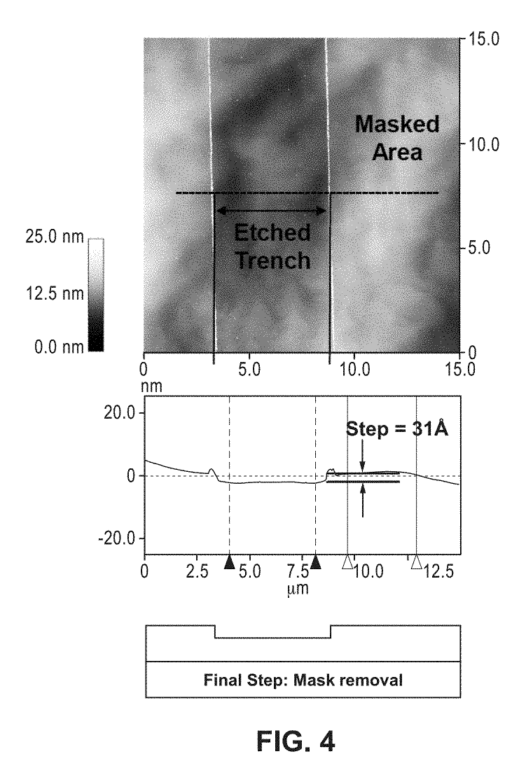

FIG. 4 shows an electronic device, which may be part of a HEMT, made using the process 460 shown in FIG. 1C. Also shown in FIG. 4 are an atomic force microscopy micrograph, showing the surface beneath the masked area and etched trench of the sample of FIG. 1C, along with a corresponding profilometry plot.

Self-Limiting Behavior of Oxidation and Etch Cycles

FIG. 5A is a plot of etch depth per cycle (in angstroms, Å) for AlGaN (with 27% Al) and GaN, for a fixed O₂ time (4 min), for varying BCl₃ cycle time. As shown in FIG. 5A, the additional etch depth per cycle gained for additional BCl₃ time per cycle levels off after ˜0.5 minutes per cycle for GaN, and after ˜1 minute per cycle for AlGaN.

FIG. 5B is a plot of etch depth per cycle, in Å, for AlGaN (with 27% Al) and GaN, for a fixed BCl₃ time (2 min), for varying O₂ cycle time. As shown in FIG. 5B, the additional etch depth per cycle gained for additional O₂ time per cycle levels off after ˜1 minute per cycle for both GaN and AlGaN. In both FIGS. 5A and 5B, the etch depth per cycle, when saturated, approaches the GaN c-lattice constant (e.g., on the order of 5.125-5.19 Å). FIGS. 5A and 5B can be used to select the O₂ and BCl₃ etch times. Full surface saturation can be used for good rate control, and partial surface saturation may be used for increased speed.

Selective Behavior of ALE

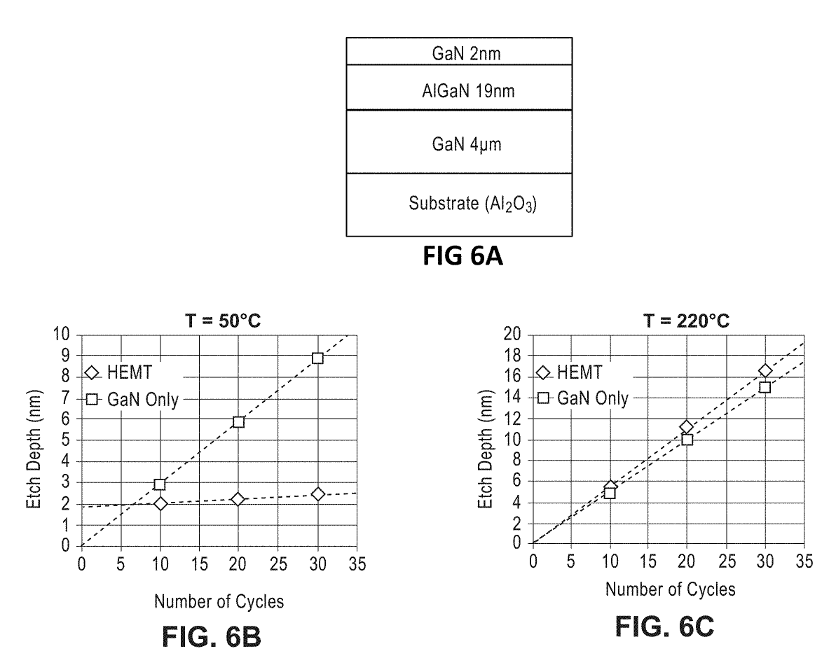

FIG. 6A is a diagram of a cross-section of an HEMT, according to some embodiments. Specifically, FIG. 6A shows a GaN HEMT epitaxial stack with a 2 nm GaN cap on 27% AlGaN. FIG. 6B is a plot of etch depth (in nanometers, nm) for the HEMT of FIG. 6A and for a GaN film alone, for varying number of BCl₃/O₂ ALE cycles, at a temperature of 50° C. The etch depths were determined via atomic force microscopy (AFM). FIG. 6B shows etch AlGaN-GaN selectivity behavior. FIG. 6C is a plot of etch depth, in nm, for the HEMT of FIG. 6A and for a GaN film alone, for varying number of etch cycles at a temperature of 220° C. As shown in FIG. 6C, the selectivity disappeared when samples were etched at 220° C. FIGS. 6A-6C can be used to select the substrate temperature, which may be below about 100° C. for stopping on Al-containing layers and above 100° C. for no selectivity.

Temperature Dependence and Aluminum Concentration

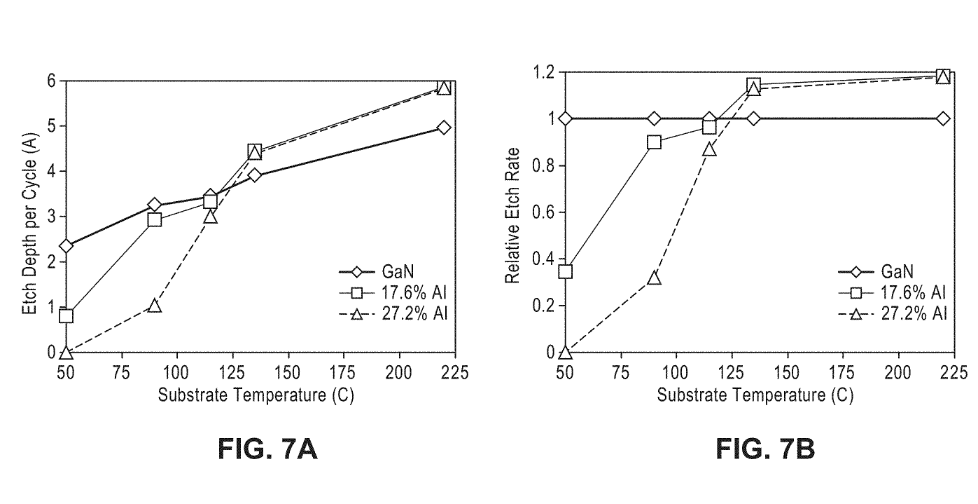

FIG. 7A is a plot of etch depth per cycle, in Å, for GaN, AlGaN with 17.6% Al, and AlGaN with 27.2% Al, for varying substrate temperature in ° C. FIG. 7B is a plot of relative etch rate for AlGaN with 17.6% Al, and AlGaN with 27.2% Al, with respect to GaN, for varying substrate temperature in ° C. As shown in FIGS. 7A and 7B, the etch rate increases monotonically with temperature for all samples (e.g., due to diffusion of oxygen into surface), and the selectivity of the etch to AlGaN is variable with temperature as well as with the Al mole fraction, for example due to the low vapor pressure of AlCl₃ compared to GaCl₃. FIGS. 7A and 7B can be used to determine temperature for selectivity crossover.

Sample Composition Spectroscopy

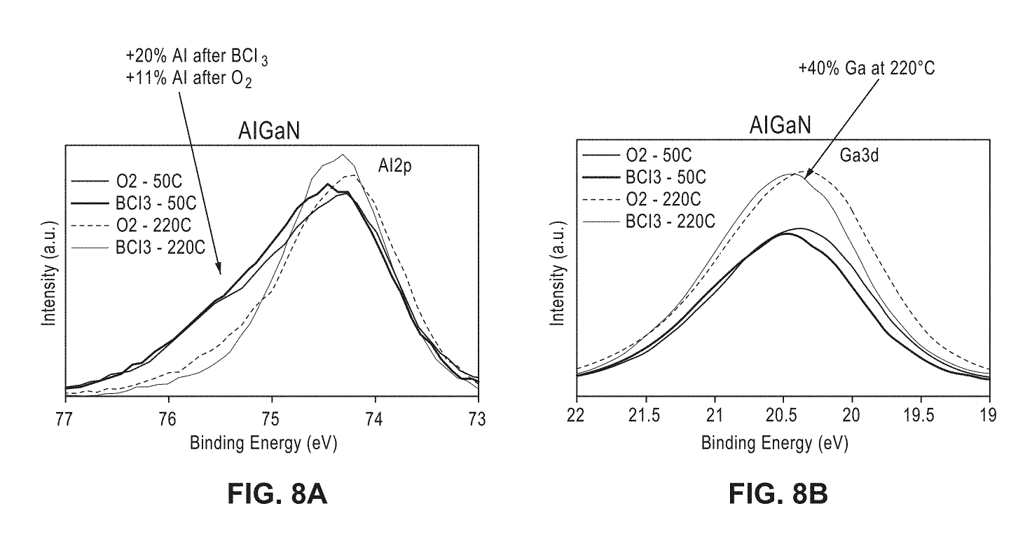

FIGS. 8A-11B illustrate sample composition spectroscopy. They show preferential removal of Ga and build-up of Al at 50° C., which suggests surface chemistry behavior for this reaction and can be used to confirm the mechanism for selectivity.

FIG. 8A is an ex-situ x-ray photoelectron spectroscopy (XPS) spectra plot (intensity vs. binding energy in electron volts, eV) for aluminum Al2p in AlGaN after exposure to O₂ and BCl₃ plasmas at 50° C. and at 220° C. The Al2p spectrum indicates significant broadening for samples etched at 50° C. (the O₂ FWHM is 130% and the BCl₃ FWHM is 150%), which is indicative of multiple bonding states for Al at 50° C.

FIG. 8B is an ex-situ XPS spectra plot for gallium Ga3d in AlGaN after exposure to O₂ and BCl₃ plasmas at 50° C. and at 220° C. The Ga3d spectrum indicates that samples etched at 50° C. have a reduced Ga fraction within the excitation volume, suggesting that the surface is depleted of a Ga signature at 50° C. on AlGaN, and suggesting that GaCl₃ is preferentially removed.

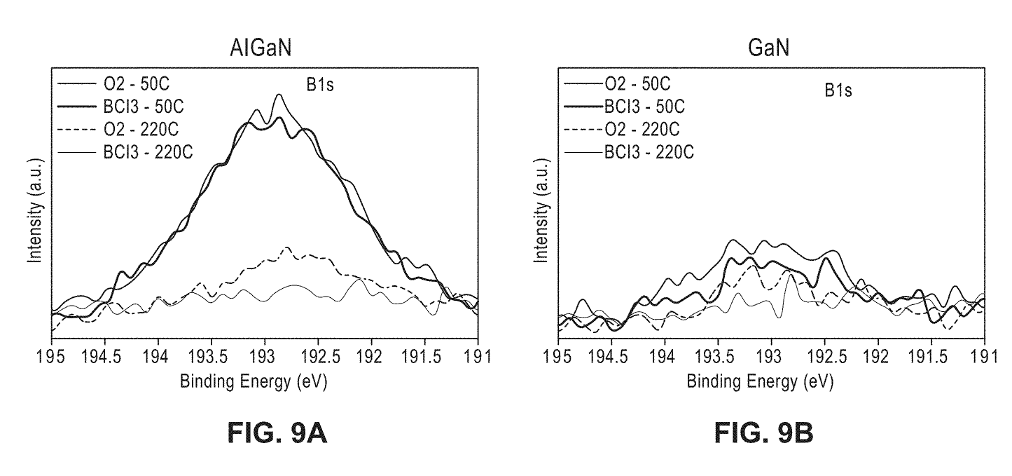

FIG. 9A is an ex-situ XPS spectra plot for boron B1s in AlGaN after exposure to O₂ and BCl₃ plasmas at 50° C. and at 220° C. The XPS indicates a significant presence of boron at 50° C. on AlGaN. The broad XPS peaks for boron and aluminum on 50° C. AlGaN are indicative of multiple bonding states, and there is a significant boron signature at 50° C. on AlGaN. FIG. 9B is an XPS spectra plot for boron B1s in GaN after exposure to O₂ and BCl₃ plasmas at 50° C. and at 220° C.

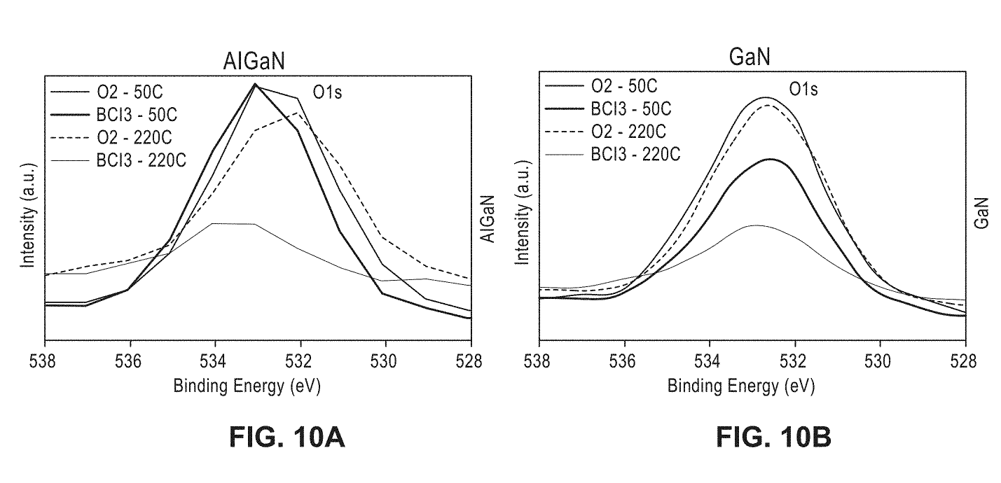

FIG. 10A is an ex-situ XPS spectra plot for oxygen O1s in AlGaN after exposure to O₂ and BCl₃ plasmas at 50° C. and at 220° C. As shown, a significant oxide signature remains after the BCl₃ etch at 50° C. All samples were likely oxidized, by virtue of it being an ex-situ measurement.

FIG. 10B is an ex-situ XPS spectra plot for oxygen O1s in GaN after exposure to O₂ and BCl₃ plasmas at 50° C. and at 220° C. An increased oxygen signature appears after BCl₃ at 50° C. for GaN, as compared to BCl₃ at 220° C.

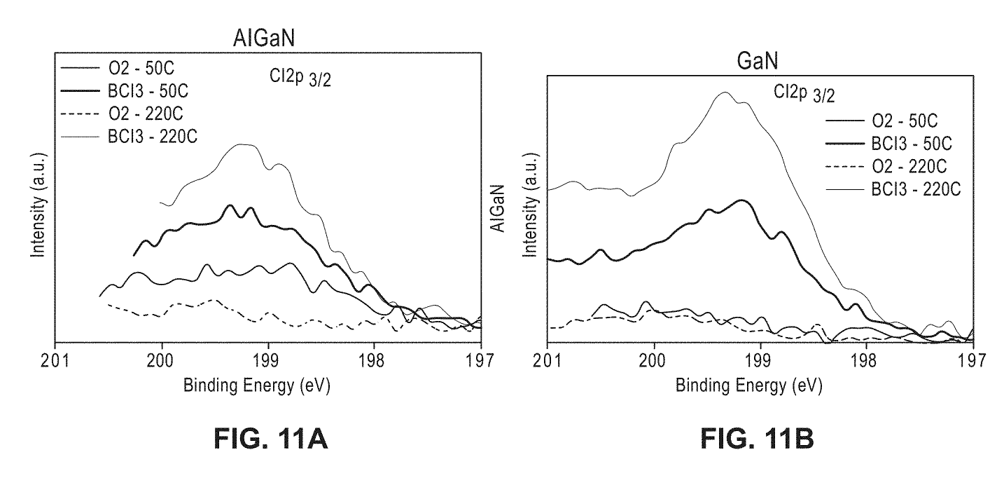

FIG. 11A is an ex-situ XPS spectra plot for chlorine Cl2p_{3/2} in AlGaN after exposure to O₂ and BCl₃ plasmas at 50° C. and at 220° C. As shown, in AlGaN, the Cl remains above background concentration following the O₂ step at 50° C., and there is an increased signature after the BCl₃ at 220° C.

FIG. 11B is an ex-situ XPS spectra plot for chlorine Cl2p_{3/2} in GaN after exposure to O₂ and BCl₃ plasmas at 50° C. and at 220° C. As shown, in GaN, the Cl is effectively removed during the oxidation step for both 50° C. and 220° C.

The XPS results shown in FIGS. 8A-11B indicate that the methods described herein may also be applicable to other Al- and Ga-containing III-V compounds (e.g., AlGaAs/GaAs or AlGaP/GaP, with higher temperatures for InGaP/InP/InGaAs), as well as for ALE of AlAs or Al metal. The higher temperatures for InGaP/InP/InGaAs desorption, which can allow these materials to act as an etch stop when an ion bombardment component is not utilized, may be too hot for conventional processing.

Reduced Sample Damage

Methods of confirming that an etch process is low-damage include: 1) transmission electron microscope (TEM) cross-section, looking for atomic disorder in the semiconductor immediately below the bottom of the etched region; 2) AFM of the semiconductor surface in the etched region, looking for dislocations or atomic steps—lattice damage prevents these from being imaged; 3) if the stop layer is thin, X-ray diffraction (XRD) can be done to see if the linewidth has stayed approximately the same (indicating no additional damage) or broadened (indicating significant damage); 4) damaged GaN and AlGaN exhibit different luminescence patterns due to defects—the region will exhibit emission of lower energy photons (e.g. red, yellow, green) rather than the expected blue/violet/UV.

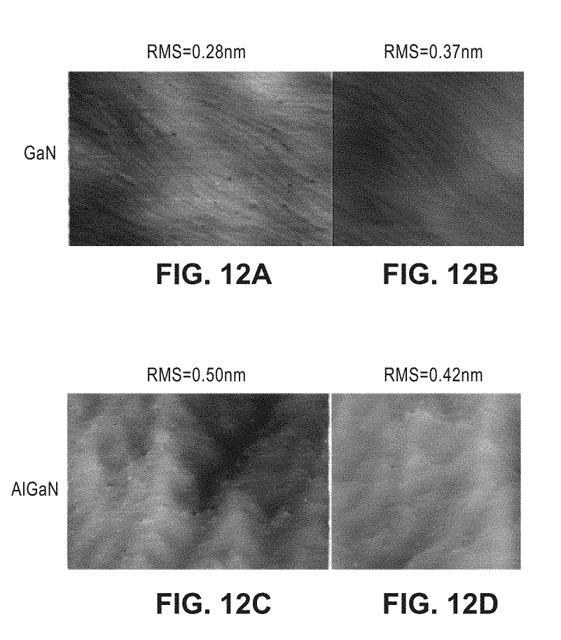

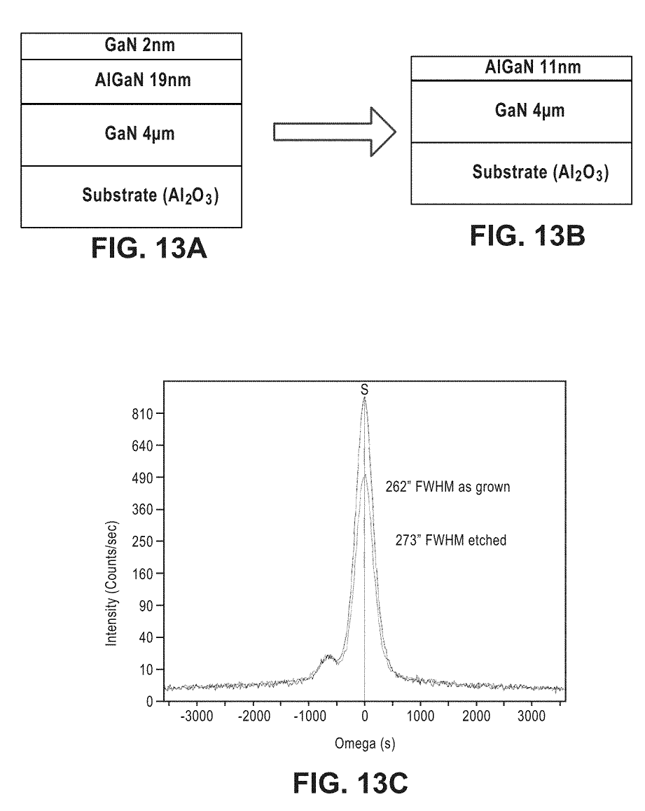

FIGS. 12A-12D are AFM scans of Etched GaN and AlGaN. FIGS. 12A and 12B show AFM scan of GaN etched for 20 cycles and as-grown, respectively. FIGS. 12C and 12D show AFM scans of AlGaN etched for 20 cycles and as-grown, respectively. These AFM scans show the low-damage nature of the AlGaN/GaN ALE methods described herein, and confirm the self-limiting behavior discussed above. They also show that epitaxial steps from growth are preserved. RMS roughness values indicate no significant roughening or morphology change. FIG. 13A is a diagram of a cross-section of an as-grown AlGaN HEMT sample prior to ALE. FIG. 13B shows the AlGaN HEMT of FIG. 13A after removal 10 nm of material via 20 cycles of ALE (“blanket etch”). FIG. 13C is an x-ray diffraction (XRD) 3-axis omega scan/rocking curve showing intensities and full widths at half maximum (FWHM) for the as-grown AlGaN HEMT sample of FIG. 13A and the etched AlGaN HEMT sample of FIG. 13B. The XRD scan indicated broadening of 11 arcsec. Without being bound by any particular theory, linewidth is an indicator of crystal quality, with smaller linewidth implying better crystalline quality. Broadening from surface reconstruction occurs when atoms at the free AlGaN surface try to minimize their energy state by moving around slightly.

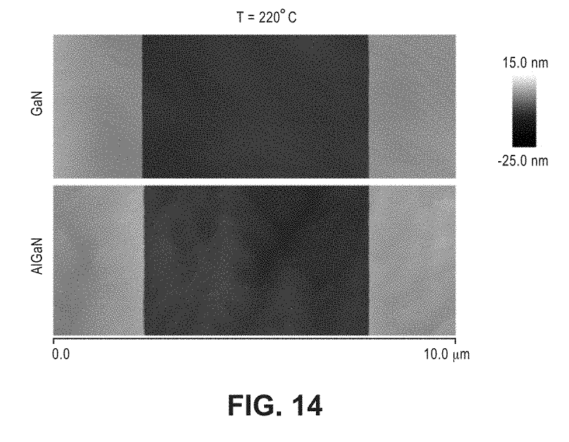

FIG. 14 shows AFM scans of a gallium nitride (GaN) film and a GaN high electron mobility (HEMT) epitaxial stack, showing an etched atomic step created via 20 BCl₃/O₂ ALE cycles at 220° C. in the center of each.

High Electron Mobility Transistors (HEMTs) Made Using ALE

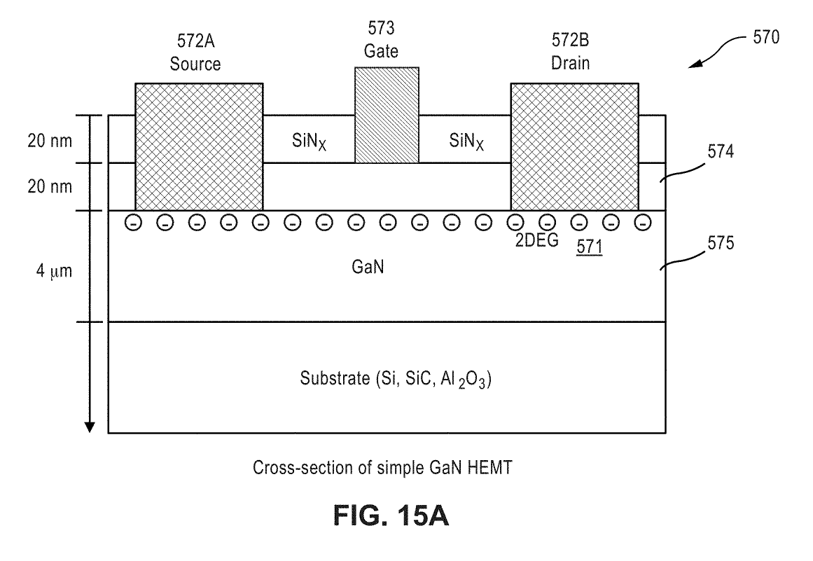

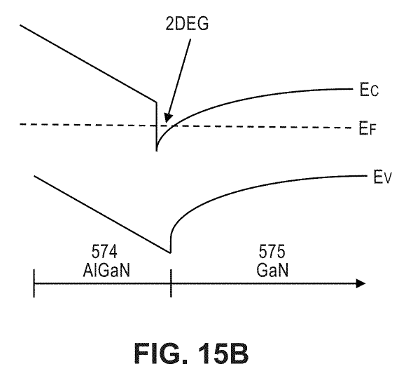

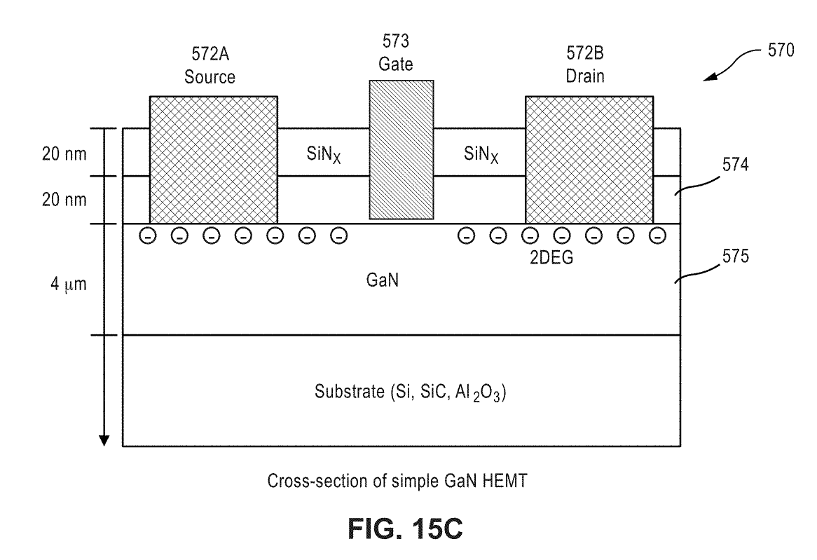

FIG. 15A is a diagram of a cross-section of a conventional depletion-mode GaN HEMT, showing a two-dimensional electron gas (“2DEG”) channel formed in the GaN 575, near the interface between AlGaN 574 and GaN 575. The 2DEG channel 571 has a high electron density and high mobility, permitting current flow between the source and drain terminals. The HEMT 570 includes a Schottky gate metal 573 and ohmic source/drain metals 572A, 572B.

FIG. 15B is an energy band diagram for the gate region of the HEMT of FIG. 15A, showing the conduction band dipping below the Fermi energy level near the AlGaN-GaN interface (within the GaN), where the 2DEG is formed, signifying the continuous conductivity 2DEG and the depletion mode operation of the HEMT of FIG. 15A. Operating closer to the 2DEG increases transconductance, improving switching speed.

FIG. 15C is a diagram of a cross-section of the GaN HEMT 570 of FIG. 15A converted into an enhancement-mode GaN HEMT according to methods described herein (with a recess formed in the AlGaN layer). As shown in FIG. 15C, the 2DEG formed in the GaN 575, near the interface between AlGaN 574 and GaN 575, is not continuous across the width of the cross-section of the device. Rather, the 2DEG is depleted such that no 2DEG channel is normally present beneath the gate. The recess formed in the AlGaN layer shifts the threshold voltage (VT) and increases the transconductance (gₘ), e.g., by a factor of two or three. The exact shift in threshold voltage depends on the epitaxial structure, gate material, and use of gate dielectric. Similarly, the transconductance depends on the recess depth and epitaxial structure.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments can be implemented in any of numerous ways. For example, embodiments of designing and making the technology disclosed herein may be implemented using hardware, software or a combination thereof. When implemented in software, the software code can be executed on any suitable processor or collection of processors, whether provided in a single computer or distributed among multiple computers.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks, wired networks or fiber optic networks.

The various methods or processes (e.g., of designing and making the technology disclosed above) outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other non-transitory medium or tangible computer storage medium) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of fabricating a device, the method comprising:
receiving a sample in a treatment chamber, the sample including a surface with an etch mask disposed thereon, the etch mask defining an exposed region of the sample surface;
introducing an oxidizing gas into the treatment chamber;
ionizing the oxidizing gas, via a remote plasma source, thereby forming a first plasma to oxidize the exposed region of the sample surface;
evacuating the oxidizing gas from the treatment chamber;
introducing a reducing gas into the treatment chamber; and
ionizing the reducing gas, via the remote plasma source, thereby forming a second plasma to reduce the exposed region of the sample surface.

2. The method of claim 1, wherein the remote plasma source comprises at least one of an inductively-coupled plasma (ICP) source or a transformer coupled plasma (TCP) source.

3. The method of claim 1, further comprising introducing an inert gas into the treatment chamber to purge the treatment chamber prior to introducing the reducing gas into the treatment chamber.

4. The method of claim 1, wherein the method does not include applying an external bias to the sample.

5. The method of claim 1, further comprising heating the sample to a temperature of at least about 100° C. to remove an Al-containing semiconductor from the sample.

6. The method of claim 5, further comprising removing reduced regions of the sample surface via thermal desorption.

7. The method of claim 1, wherein the oxidizing gas comprises at least one of oxygen (O₂), nitric oxide (NO), or nitrous oxide (N₂O).

8. The method of claim 1, wherein the reducing gas comprises at least one of boron trichloride (BCl₃), silicon tetrachloride (SiCl₄), carbon tetrachloride (CCl₄), other chlorocarbons (CₓCl_{y}), or hydrochlorocarbons (CₓH_{y}Cl_{z}).

9. The method of claim 1, further comprising:
introducing an inert gas into the treatment chamber to aid ionization of the oxidizing gas and/or the reducing gas.

10. The method of claim 9, wherein introducing the inert gas comprises admitting at least one of argon, helium, neon, or nitrogen into the treatment chamber.

11. The method of claim 1, wherein the sample comprises a semiconductor material.

12. The method of claim 11, wherein the semiconductor material comprises at least one of a III-Nitride (III-N) material or a III-Arsenide (III-As) material.

13. The method of claim 11, wherein the semiconductor material comprises at least one of aluminum gallium nitride (AlGaN) or aluminum nitride (AlN).

14. The method of claim 1, wherein the second plasma reduces the exposed region of the sample surface to yield an etch rate of the exposed region of the sample surface of about 1 Angstrom per second.

15. A product produced according to the method of claim 1.

16. An apparatus for remote plasma microfabrication of a sample, the apparatus comprising:
a process chamber to process a surface of the sample received therein;
a power supply, coupled to the process chamber, to power a remote plasma source so as to deliver a remote plasma to the surface of the sample to alternately oxidize and reduce the surface of the sample; and
a heater, disposed in the process chamber, to heat the sample to a temperature sufficient to thermally desorb components of the surface of the sample.

17. The apparatus of claim 16, wherein the remote plasma is an inductively coupled plasma (ICP).

18. The apparatus of claim 16, further comprising:
a vacuum pump, in fluid communication with the process chamber, to evacuate the process chamber between oxidizing and reducing the surface of the sample.

19. The apparatus of claim 18, further comprising:
a gas inlet, in fluid communication with the process chamber, to receive an inert gas to purge the process chamber before and/or after evacuating the process chamber between oxidizing and reducing the surface of the sample.

20. A method of patterning a III-N semiconductor substrate, the method comprising:
(A) placing the III-N semiconductor substrate in a vacuum chamber;
(B) evacuating the vacuum chamber;
(C) heating the III-N semiconductor substrate to a temperature of at least about 100° C.;
(D) introducing an oxidizing gas into the vacuum chamber;
(E) ionizing the oxidizing gas, via an inductively-coupled plasma (ICP) source, so as to oxidize at least a portion of a surface of the III-N semiconductor substrate;
(F) evacuating the oxidizing gas from the vacuum chamber;
(G) introducing a reducing gas into the vacuum chamber after the oxidizing gas has been evacuated from the vacuum chamber;
(H) ionizing the reducing gas, via the ICP source, so as to reduce the exposed region of the at least a portion of the surface of III-N semiconductor substrate; and
(I) evacuating the reducing gas from the vacuum chamber.

21. The method of claim 20, further comprising:
repeating steps (E) through (I) at least once before removing the III-N semiconductor substrate from the vacuum chamber.

22. The method of claim 20, further comprising:
introducing an inert gas into the vacuum chamber to purge the vacuum chamber after step (G) and removing the inert gas prior to step (H).

23. The method of claim 20, wherein the oxidizing gas comprises at least one of oxygen (O₂), nitric oxide (NO), or nitrous oxide (N₂O).

24. The method of claim 20, wherein the reducing gas comprises at least one of boron trichloride (BCl₃), silicon tetrachloride (SiCl₄), carbon tetrachloride (CCl₄), other chlorocarbons (CₓCl_{y}), or hydrochlorocarbons (CₓH_{y}Cl_{z}).

25. The method of claim 20, further comprising:
introducing an inert gas into the treatment chamber to aid ionization of the oxidizing gas and/or the reducing gas.

26. The method of claim 25, wherein introducing the inert gas comprises admitting at least one of argon, helium, neon, or nitrogen into the treatment chamber.

27. The method of claim 20, wherein no bias is applied to the III-N semiconductor substrate.

28. A product produced according to the method of claim 20.
